(19) United States
(12) Patent Application Publication
(10) Pub. No.: US 2021/0215564 A1
(43) Pub. Date: Jul. 15, 2021

(54) MOTOR STATE MONITORING DEVICE AND MOTOR STATE MONITORING METHOD

(71) Applicant: SZ DJI TECHNOLOGY CO., LTD., Shenzhen (CN)

(72) Inventors: Xiaoping HONG, Shenzhen (CN); Huan HE, Shenzhen (CN); Likui ZHOU, Shenzhen (CN); Xiang LIU, Shenzhen (CN); Huai HUANG, Shenzhen (CN)

(21) Appl. No.: 17/214,912

(22) Filed: Mar. 28, 2021

Related U.S. Application Data
(63) Continuation of application No. PCT/CN2018/108855, filed on Sep. 29, 2018.

(51) Int. Cl. G01M 1/22; G01C 3/02

(52) U.S. Cl. CPC G01M 1/22; G01C 3/02

(57) ABSTRACT

The present disclosure provides a motor state monitoring device. The motor state monitoring device includes a receiver disposed separately from a motor and configured to receive a measured signal emitted by the motor without contact; and a signal processing unit connected to the receiver and configured to determine a state of the motor based on the measured signal, and generate a state signal indicating the state of the motor.

### CROSS-REFERENCE TO RELATED APPLICATION

This application is a continuation of International Application No. PCT/CN2018/108855, filed on Sep. 29, 2018, the entire content of which is incorporated herein by reference.

### TECHNICAL FIELD

The present disclosure relates to the technical field of motor monitoring and, more specifically, to a motor state monitoring device and a motor state monitoring method.

### BACKGROUND

As a power source or a device that provide power for other devices, motors play an important role in many fields. For example, motors are used in products such as unmanned aerial vehicle (UAV), robots, electrical bicycles, electric vehicles, industrial equipment, generators, and lidars to realize the conversion between electrical energy and mechanical energy.

Often, a motor may be in a long and unstable payload working condition, and aging of the motor needs to be monitored and addressed. However, many issues that occur during use can only be discovered and dealt with after a failure has occurred, such as a failure to start or a malfunction during motor operation.

### SUMMARY

On aspect of the present disclosure provides a motor state monitoring device. The motor state monitoring device includes a receiver disposed separately from a motor and configured to receive a measured signal emitted by the motor without contact; and a signal processing unit connected to the receiver and configured to determine a state of the motor based on the measured signal, and generate a state signal indicating the state of the motor.

Another aspect of the present disclosure provides a motor state monitoring method. The method includes using a receiver to receive a measured signal emitted by a motor without contact; and determining a state of the motor based on the measured signal, and generating a state signal indicating the state of the motor.

Another aspect of the present disclosure provides a distance measuring device. The device includes a scanning module including a motor and a prism with uneven thickness, the motor being configured to drive the prism to rotate; and a motor state monitoring device configured to monitor a state of the motor. The motor state monitoring device includes a receiver disposed separately from the motor and configured to receive a measured signal emitted by the motor without contact; and a signal processing unit connected to the receiver and configured to determine the state of the motor based on the measured signal, and generate a state signal indicating the state of the motor.

### BRIEF DESCRIPTION OF THE DRAWINGS

In order to illustrate the technical solutions in accordance with the embodiments of the present disclosure more clearly, the accompanying drawings to be used for describing the embodiments are introduced briefly in the following. It is apparent that the accompanying drawings in the following description are only some embodiments of the present disclosure. Persons of ordinary skill in the art can obtain other accompanying drawings in accordance with the accompanying drawings without any creative efforts.

FIG. 1 is a block diagram of a motor state monitoring device according to an embodiment of the present disclosure.

FIG. 2 is a block diagram of the motor state monitoring device according to another embodiment of the present disclosure.

FIG. 3 is a flowchart of a motor state monitoring method according to an embodiment of the present disclosure.

FIG. 4 is a block diagram of a distance measuring device according to an embodiment of the present disclosure.

FIG. 5 is a block diagram of the distance measuring device using a coaxial optical path according to an embodiment of the present disclosure.

### DETAILED DESCRIPTION OF THE EMBODIMENTS

Technical solutions of the present disclosure will be described in detail with reference to the drawings. It will be appreciated that the described embodiments represent some, rather than all, of the embodiments of the present disclosure. Other embodiments conceived or derived by those having ordinary skills in the art based on the described embodiments without inventive efforts should fall within the scope of the present disclosure.

The illustrative embodiments will be described in detail, examples of which are shown in the accompanying drawings. In the following descriptions, when the accompanying drawings are referenced to, unless there are other express indication, the same numbers in different accompanying drawings indicate the same or similar elements. The implementation methods described in the following illustrative embodiments do not represent all implementation methods consistent with the present disclosure. Conversely, they are only examples of the device and method that are consistent with some aspects of the present disclosure that are described in the accompanying claims.

It should be understood that in the present disclosure, relational terms such as first and second, etc., are only used to distinguish an entity or operation from another entity or operation, and do not necessarily imply that there is an actual relationship or order between the entities or operations. Similarly, “a” or “one” and similar terms do not limit the number of features, but only indicate that there exists at least one feature. In addition, unless otherwise noted, the terms “front,” “back” (or “rear”), “lower,” and/or “upper” and other similar terms are only for the convenience of descriptions, and are not intended to limit to a particular position, location, or space orientation. The terms “comprise,” “comprising,” “include,” and the like specify the presence of stated features, steps, operations, elements, and/or components appearing following these terms are included in an element or object appearing before these terms, but do not preclude the presence or addition of one or more other features, steps, operations, elements, components, and/or groups. When a first component is referred to as “connected” to or with a second component, it is intended that the first component may be directly connected to or with the second component or may be indirectly connected to or with the second component via an intermediate component. The connection may include mechanical and/or electrical connections. The connection may be permanent or detachable. The electrical connection may be wired or wireless. As used herein, the term “plurality” indicates at least two.

An embodiment of the present disclosure provides a motor state monitoring device. The motor state monitoring device may include a receiver and a signal processing unit. The receiver may be arranged separately from the motor, and configured to receive a measured signal emitted by the motor without contacting the motor. The signal processing unit may be connected with the receiver, and configured to determine the state of the motor based on the measured signal, and generate a state signal indicating the state of the motor.

The motor state monitoring device can receive the measured signal emitted by the motor without a direct contact, and determine the state of the motor based on the measured signal. The measured signal emitted by the motor into the space can reflect small abnormal changes of the motor. In this way, small abnormal changes of the motor can be detected in time before the health of the motor deteriorates, thereby avoiding further deterioration and damage. In addition, separating the receiver from the motor can prevent the abnormal vibration and magnetic field caused by the operation of the motor from causing negative influence and damage to the motor state monitoring device.

An embodiment of the present disclosure provides a motor state monitoring method to motor the state of a motor. The motor state monitoring method may include using a receiver that is not in contact with the motor to receive the measured signal emitted by the motor; and determining the state of the motor based on the measured signal, and generating a state signal indicating the state of the motor.

Exemplary embodiments will be described with reference to the accompanying drawings. In the case where there is no conflict between the exemplary embodiments, the features of the following embodiments and examples may be combined with each other.

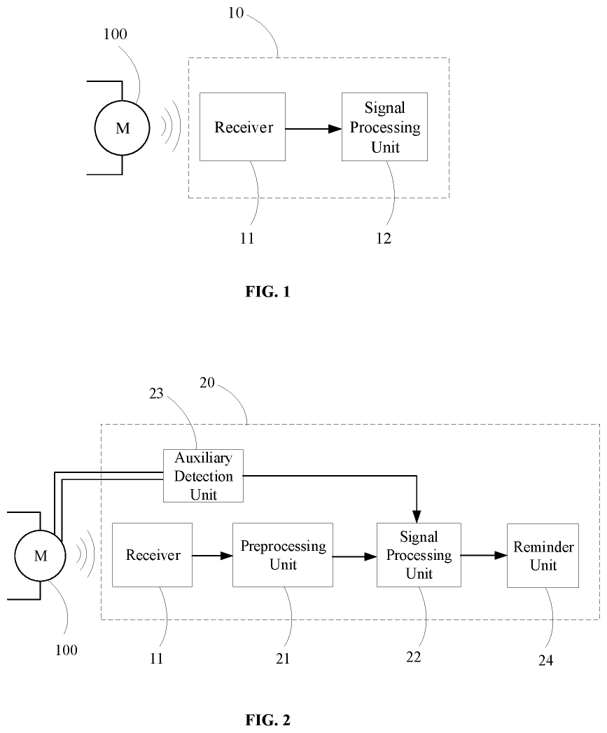

FIG. 1 is a block diagram of a motor state monitoring device 10 according to an embodiment of the present disclosure. The motor state monitoring device 10 can be used to monitor the state of a motor 100. The motor 100 can be used in, but is not limited to, products such as UAVs, robots, electric bicycles, electric vehicles, industrial equipment, generators, and lidars to realize the conversion between electrical energy and mechanical energy. The motor state monitoring device 10 includes a receiver 11 and a signal processing unit 12.

The receiver 11 can be arranged separately from the motor 100 for receiving, without a direct contact, a measured signal emitted by the motor 100. The signal processing unit 12 can be connected to the receiver 11 for determined the state of the motor 100 based on the measured signal, and generate a state signal indicating the state of the motor 100. The measured signal emitted by the motor 100 into the space can reflect small abnormal changes of the motor 100. The motor state monitoring device 10 can non-contactly receive the measured signal emitted by the motor 100 and determine the state of the motor 100 based on the measured signal. In this way, small abnormal changes of the motor 100 can be detected in time before the health of the motor 100 deteriorates, and the state of the motor 100 can be reacted more actively. Therefore, the motor 100 can be overhauled when the fault is relatively small, to avoid further deterioration and damage of the fault, reduce the overhaul time, and improve the work efficiency. In addition, separating the receiver 11 from the motor 100 can prevent the abnormal vibration and magnetic field caused by the operation of the motor 100 from causing negative influence and damage to the motor state monitoring device 10. Further, the motor state monitoring device 10 can continuously monitor the state of the motor online in real time during the operation of the motor 100. In this way, state change of the motor can be tracked over time, which is advantageous for identifying the aging trend of the motor and improving the motor technology. Moreover, the quality of the motor can be inspected by monitoring the state of the motor in operation during the motor production inspection, and the inspection is easy to conduct.

In some embodiments, the measured signal may include one or more of a sound wave signal or an electromagnetic wave signal. In one embodiment, the measured signal includes a sound wave signal, and the sound wave signal may include audio sound waves, ultrasonic waves, and/or infrasound waves. The motor 100 will vibrate when it is running, as such, the motor 100 will emit acoustic signals. When the motor 100 works under the designed conditions, the vibrations and the sound wave signals emitted during operation are kept in a certain stable state. However, when the machining and/or assembly errors of the motor parts exceed an allowable range, and/or issues such as again and wear due to long-term use, the motor 100 will produce abnormal vibrations and produce abnormal acoustic signals.

In some cases, due to individual differences and manufacturing accuracy during production, defective products will be produced, which will cause abnormal vibrations when the motor 100 is running, and generate abnormal acoustic signals. For example, due to the manufacturing limitation of the rotor of the motor 100, the rotor machining error may cause abnormal vibrations due to mass imbalance during operation, which can generate abnormal acoustic signals. In another example, the assembly errors between the rotor, bearing, stator, and other parts may also cause the motor 100 to vibrate abnormally during the working process, and generate abnormal acoustic signals. In another example, the magnetic force of the rotor pole of the motor 100 may be strong when the magnetic pole is close to the stator pole, and the magnetic force may be weak when the rotor pole is far away from the stator pole. Change in the strength of the magnetic force may cause regular changes in the rotation speed of the rotor, thereby causing the motor 100 to vibrate and generate acoustic signals. In some cases, for example, mechanical wear, material corrosion, etc. may cause unevenness of the bearing surface of the motor 100, which may cause abnormal vibration during operation, thereby generating abnormal acoustic signals.

The change of the motor state may cause the acoustic signal emitted by the motor 100 to change. The acoustic signal can reflect the state of the motor 100. Therefore, by detecting the acoustic signal, the state of the motor 100 can be determined based on the acoustic signal. The vibration of the motor 100 mainly reflects the motor speed, mechanical characteristics, wear, etc., and the vibration of the motor can be accompanied by the generation of sound waves. Therefore, by detecting the sound waves, the motor speed, motor mechanical characteristics, wear, and other health condition can be monitored. The minute vibration of the motor 100 may not be easily detected by the vibration sensor. Further, since the bandwidth of vibration detection is limited, it may be difficult to find a suitable vibration sensor to detect the vibration. However, small vibrations can also produce acoustic signals that can be easily collected. The changes in the acoustic signals caused by the state of the motor are generally very rapid. Therefore, by detecting the acoustic signal to monitor the state of the motor 100, the small abnormal changes of the motor 100 can be identified more timely. In addition, the frequency of the acoustic signal emitted by the motor 100 can cover a wide range, from infrasound to very high frequency ultrasonic waves, therefore, it is easy to find a suitable receiver for collecting the acoustic signals, and more information can be obtained to determine the state of the motor. Further, the acoustic signal is transmitted from the motor 100 through the air, and the receiver 11 can receive the acoustic signal in a non-contact manner, such that the receiver 11 can be separated from the motor 100. In this way, the abnormal vibration and magnetic field caused by the abnormal operation of the motor 100 can be prevented from causing adverse effects and damage to the components such as the receiver 11.

The receiver 11 can receive acoustic signals and convert the acoustic signals into electrical signals. In some embodiments, the receiver 11 may include an acoustic receiver for receiving acoustic signals. The acoustic receiver may include a microphone, an accelerometer, a vibration sensor, a piezoelectric crystal, and/or a barometer. The signal processing unit 12 may determine the state of the motor 100 based on the electrical signal converted from the acoustic signal.

In some embodiments, the measured signal may include electromagnetic wave signals. In one embodiment, the electromagnetic wave signals may include one or more of radio waves, microwaves, infrared rays, visible light, ultraviolet rays, X-rays, and gamma rays. For example, the electromagnetic wave signals may include power frequency electromagnetic wave signals. Changes in the current and/or voltage of the motor 100 may cause change in electromagnetic wave signals. The motor current and/or voltage may reflect whether the motor 100 is short-circuited, disconnected, operating in abnormal speed, or abnormal due to mechanical loss. Therefore, the abnormal state of the motor 100 described above can be monitored by monitoring the electromagnetic wave signal. When there is a small abnormality in the motor 100, the current and/or voltage change may not be significant, and the electromagnetic wave signal changes may be relatively significant. As such, small abnormality of the motor 100 can be discovered in time by monitoring the electromagnetic wave signal.

The receiver 11 may include an antenna for receiving electromagnetic wave signals. The antenna may convert the electromagnetic wave signals into electrical signals, and the signal processing unit 12 may determine the state of the motor 100 based on the electrical signals converted from the electromagnetic wave signals. The antenna may not be in contact with the motor 100, and may receive the electromagnetic wave signals in a non-contact manner to avoid being affected by the vibration of the motor 100 or the like.

In some embodiments, the electromagnetic wave signals may include infrared rays. The temperature change of the motor 100 may cause the infrared rays emitted by the motor 100 to change. The temperature of the motor 100 mainly reflects the power consumption and wear state of the motor 100, therefore, the power consumption and wear state of the motor 100 can be monitored by monitoring the infrared rays. When there is a small abnormality in the motor 100, the temperature change may not be significant, but the infrared ray changes may be relatively significant. As such, small abnormality of the motor 100 can be discovered in time by monitoring the infrared ray.

The receiver 11 may include an infrared receiving tube for receiving infrared rays. The infrared receiving tube may convert infrared rays into electrical signals, and the signal processing unit 12 may determine the state of the motor 100 based on the electrical signals converted from the infrared rays. The infrared receiving tube may not be in contact with the motor 100, and may sense the infrared rays in a non-contact manner to avoid being affected by the vibration of the motor 100 or the like.

In some embodiments, the electromagnetic wave signals may include power frequency electromagnetic wave signals and infrared rays. The receiver 11 may receive the power frequency electromagnetic wave signals and the infrared rays. The receiver 11 may include an antenna for receiving power frequency electromagnetic wave signals and an infrared receiving tube for receiving infrared rays. Through the detection of power frequency electromagnetic wave signals and infrared rays, more motor information can be obtained, the state of different aspects of the motor 100 can be determined, and the state of the motor 100 can be determined more accurately.

In some embodiments, the measured signal may include acoustic signals and electromagnetic wave signals. The receiver 11 may receive the acoustic signals and the electromagnetic wave signals to obtain more motor information, determine the state of the motor 100 from different aspects, and determine the state of the motor 100 more accurately.

In some embodiments, the receiver 11 may be used to receive signals. The signals may include the measured signals and the noise signals mixed in the measured signals, and the signal processing unit 12 may be used to identify the measured signals. For example, the acoustic signals received by the receiver 11 may include the acoustic signals and the noise signals emitted by the motor 100, and the noise signals may include, for example, noise from other devices other than the motor 100 and the surrounding environment. The receiver 11 may convert all receives signals into electrical signals, and the signal processing unit 12 may process the electrical signals, remove the electrical signals corresponding to the noise signals, and identify the electrical signals corresponding to the measured signals. Subsequently, the measured signals can be further processed to determine the motor state. In this way, noise can be removed, the measured signals can be retained, and the influence of the noise signals on the determination of the motor state can be avoided.

The state of the motor 100 may include a normal state and an abnormal state. The signal processing unit 12 may determine whether the motor 100 is in the normal state or the abnormal state by analyzing the measured signals. In some embodiments, when the motor 100 is in the abnormal state, the signal processing unit 12 may determine the type of the abnormal state of the motor 100 and/or the abnormal position in the motor 100 based on the measured signals. The types of the abnormal states may include unbalanced rotor rotation, abnormal rotation speed, abnormal bearing vibration, abnormal current, abnormal voltage, short circuit, open circuit, etc. The abnormal positions may include rotors, bearings, coils, brushes, etc.

In some embodiments, the signal processing unit 12 may be used to determine the state of the motor based on the frequency spectrum and/or amplitude of the measured signal. When one or more or two or more of the spectrum abnormality, amplitude abnormality, or phase abnormality of the measured signals are abnormal, the state of the motor can be determined as abnormal. In some embodiments, the signal processing unit 12 may be used to determine the state of the motor based on one or more of the bandwidth, frequency, amplitude, spectrum change, amplitude change, phase size, or phase change of the measured signal. In some embodiments, when one or more of the bandwidth, frequency, amplitude, spectrum change, amplitude change, phase size, or phase change are abnormal, the state of the motor can be determined as abnormal. In some embodiments, when the motor is in the normal state, the frequency of the measured signal may be within a normal frequency range with a certain bandwidth. When the bandwidth of the frequency spectrum of the measured signal is inconsistent with the bandwidth of the normal state, the state of the motor can be determined as abnormal. When the frequency of the measured signal exceeds a frequency threshold, the state of the motor can be determined as abnormal. When the amplitude of the measured signal exceeds an amplitude threshold, the state of the motor can be determined as abnormal.

When the spectrum change of the measured signal is inconsistent with the spectrum change of the measured signal in the normal state, the state of the motor can be determined as abnormal. In some embodiments, the signal processing unit 12 may be used to determine that the state of the motor is abnormal when the measured signal includes one or more of the following condition: one or more frequency spectrums in the motor normal state disappear, frequency band outside the frequency spectrum under the motor normal state includes a specific frequency spectrum, the same frequency band repeatedly appears, the time of the frequency spectrum in the motor normal state is abnormal, or the phase of the signal in the frequency spectrum is abnormal. When one or more of the above conditions occur, it may indicate that the spectrum of the measured signal changed abnormally, and the state of the motor can be determined as abnormal. When the amplitude change of the measured signal is inconsistent with the amplitude change in the normal state, the state of the motor can be determined as abnormal. In other embodiments, when the combination of two or more of the bandwidth, frequency, amplitude, spectrum change, amplitude change, phase size, or phase change is abnormal, the state of the motor can be determined as abnormal.

The normal state determination conditions described above can be stored in a normal state knowledge base, and the signal processing unit 12 may extract the normal state determination conditions from the normal state knowledge base. The abnormal state determination conditions described above can be stored in an abnormal state knowledge base, and the signal processing unit 12 may extract the abnormal state determination condition from the abnormal state knowledge base.

In some embodiments, the signal processing unit 12 may be used to compare the measured signal with the corresponding signal model to determine the state of the motor. The signal model may include a normal signal model under the normal state of the motor and/or an abnormal signal model under the abnormal state of the motor. In one embodiment, the signal processing unit 12 may determine whether the motor state is normal by comparing the measured signal with the normal signal model. When the measured signal matches the normal signal model, the state of the motor can be determined as normal. Otherwise, the state of the motor can be determined as abnormal. In one embodiment, when the state of the motor is abnormal, the measured signal can be further compared with the abnormal signal model to determine the type of abnormality and the position where the abnormality occurs. In another embodiment, the signal processing unit 12 may compare the measured signal and the abnormal signal model to determine whether the state of the motor is abnormal. When the measured signal matches the abnormal signal model, the state of the motor can be determined as abnormal. Otherwise, the state of the motor can be determined as normal. Similarly, the type of abnormality and the position where the abnormality occurs can be determined by comparing the measured signal and the abnormal signal model. In this way, the state of the motor can be quickly determined. In some embodiments, the state of the motor can be determined by combining the state determination conditions and the signal model, such that the health of the motor can be detected more accurately. The normal signal model can be stored in the normal state knowledge base, and the abnormal signal model can be stored in the abnormal state knowledge base.

In some embodiments, the initial normal state knowledge base and abnormal state knowledge base can be established in advance based on experience. The normal signal model, the normal determination conditions, the abnormal signal model, and/or the abnormal determination conditions may be predetermined based on experience, such that the initial normal state knowledge base and abnormal state knowledge base can be established. During the motor state monitoring process, the normal state knowledge base and the abnormal state knowledge base can be continuously updated. In some embodiments, the signal processing unit 12 may be used to update the normal state knowledge base when the state of the motor is determined to be normal, and add the characteristics of the measured signal corresponding to the normal state of the motor into the normal state knowledge base. The normal state knowledge base may include the normal signal models and/or the normal state determination conditions. The signal processing unit 12 may be used to update the abnormal state knowledge base when the state of the motor is determined to be abnormal, and add the characteristics of the measured signal corresponding to the abnormal state of the motor into the abnormal state knowledge base. The abnormal state knowledge base may include the abnormal signal models and/or the abnormal state determination conditions

When the state of the motor cannot be determined based on the information in the normal state knowledge base and the abnormal state knowledge base, for example, the measured signal does not match the normal signal model and the abnormal signal model, and the measured signal does not meet the normal determination conditions and the abnormal determination conditions, the state of the motor may be determined by other auxiliary detection methods (such as the detection of voltage, current, vibration, and temperature), and the characteristics of the corresponding measured signal can be extracted, the corresponding signal model and/or determination conditions can be established, and the corresponding state knowledge can be updated. In this way, self-learning and updating can be realized, and the state knowledge base can be continuously improved, such that the state knowledge base is more in line with the characteristics of the corresponding motor, and the health state of the corresponding motor can be detected more easily and accurately. The mechanical characteristics and operating characteristics of different motors may be different. After constantly updating the knowledge base of different states corresponding to different motors, the characteristics of the measured signals of different motors can be better reflected, thereby making the detection more accurate.

In some embodiments, the signal processing unit 12 may be used to compare the measured signal of the designated frequency band with the signal model of the designated frequency band to determine the state of the motor. The signal processing unit 12 may determine the state of the motor by analyzing the measured signal of a specific frequency band. The frequency band with relatively concentrated and significant characteristics of the measured signal can be selected as the designated frequency band. When the measured signal has significant amount of information, the state of the motor can be detected more quickly. In other embodiments, the signal processing unit 12 may be used to compare the measured signal of the full spectrum with the signal model of the full spectrum to determine the state of the motor. The signal processing unit 12 may determine the state of the motor by analyzing the measured signal of the full spectrum. In this way, the state of the motor can be determined more accurately.

In some embodiments, the signal processing unit 12 may include devices with programmable logic processing capabilities, such as processors, FPGAs, mechanical calculators, etc.

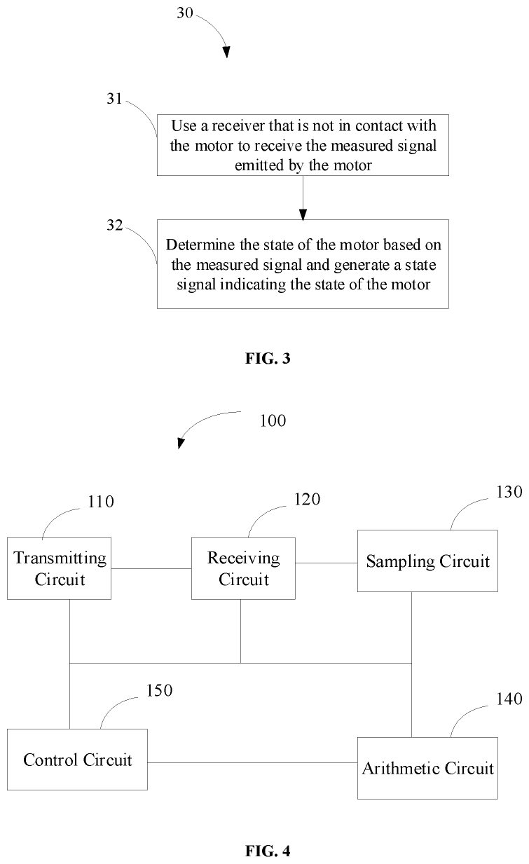

FIG. 2 is a block diagram of a motor state monitoring device 20 according to another embodiment of the present disclosure. The motor state monitoring device 20 shown in FIG. 2 is similar to the motor state monitoring device 10 shown in FIG. 1. Compared with the motor state monitoring device 10 shown in FIG. 1, the motor state monitoring device 20 shown in FIG. 2 further includes a preprocessing unit 21. The receiver 11 can convert the measured signal into an electrical signal. The preprocessing unit 21 can be connected between the receiver 11 and a signal processing unit 22. The preprocessing unit 21 can be used to process the electrical signal converted by the receiver 11 for the signal processing unit 22. The preprocessing unit 21 can perform preprocessing on the electrical signal, such that the signal processing unit 22 can perform further processing and analysis on the electrical signal.

In some embodiments, the electrical signal generated by the receiver 11 may be an analog signal. For example, a microphone can convert an acoustic signal into an analog electrical signal. The preprocessing unit 21 may include an analog-to-digital (A-D) conversion module, and the A-D conversion module can be used to convert an analog signal into a digital signal, and provide it to the signal processing unit 22. The signal processing unit 22 can process and analyze the digital signal. In other embodiments, the preprocessing unit 21 may perform other processing on the electrical signal output by the receiver 11, such as filtering the electrical signal, and/or amplifying the electrical signal.

In some embodiments, the preprocessing unit 21 and the receiver 11 may be integrated. The preprocessing unit 21 may be combined with the receiver 11 into one device. For example, the A-D conversion module may be assembled in the housing of the microphone and integrated with the microphone. In other embodiments, the preprocessing unit 21 and the receiver 11 may be separated from each other. The preprocessing unit 21 and the receiver 11 may be independent devices and may be electrically connected through an interface, an electrical connection wire, and the like.

In the embodiment shown in FIG. 2, the motor state monitoring device 20 also includes an auxiliary detection unit 23 for detecting auxiliary measured signals of the motor 100 that are different from the measured signals. The signal processing unit 22 may be electrically connected to the auxiliary detection unit 23, and may be used to assist in determining the state of the motor by using the auxiliary measured signal, such that the state of the motor can be more accurately determined. The auxiliary measured signal may include one or more of the current, voltage, vibration, or temperature of the motor 100. Correspondingly, the auxiliary detection unit 23 may include one or more of a current detection circuit for detecting the current of the motor 100, a voltage detection circuit for detecting the voltage of the motor 100, a vibration detection device for detecting the vibration of the motor 100, or a temperature sensor for detecting the temperature of the motor 100. The current detection circuit and/or the voltage detection circuit may be electrically connected to the circuit of the motor 100. The vibration detection device may be in direct contact with the motor 100 or may be connected with the motor 100 through a rigid element. In some embodiments, the vibration detection device may include a vibration sensor, an accelerometer, and/or a gyroscope. The temperature sensor may be in direct contact with the motor 100.

In some embodiments, when the measured signal cannot match the information in the normal state knowledge base and the abnormal state knowledge base, and the state of the motor cannot be determined through the normal state knowledge base and the abnormal state knowledge base, the signal processing unit 22 may determine the state of the motor through the auxiliary measured signal. The signal processing unit 22 may extract the characteristics of the measured signal corresponding to the auxiliary measured signal at this time, and update the corresponding signal model and/or state determination conditions. When the signal processing unit 22 determines that the state of the motor is normal based on the auxiliary measured signal, the signal processing unit 22 may update the normal signal model and/or the normal state determination conditions in the normal state knowledge base based on the corresponding measured signal. Similarly, when the signal processing unit 22 determines that the state of the motor is abnormal based on the auxiliary measured signal, the signal processing unit 22 may update the abnormal signal model and/or the abnormal state determination condition in the abnormal state knowledge base based on the corresponding measured signal. In this way, the motor state monitoring device 20 can perform self-learning during the operation of the motor, update the determination model and conditions in time, and improve the efficiency and accuracy of motor state detection. The signal processing unit 22 shown in FIG. 2 may also include the function of the signal processing unit 12 shown in FIG. 1, which will not be repeated here.

In the embodiment shown in FIG. 2, the motor state monitoring device 20 includes a reminder unit 24. The reminder unit 24 can be connected to the signal processing unit 22, and configured to send a reminder message when the state of the motor is abnormal, such that the user can be reminded in time. The reminder unit 24 can inform the user of the abnormal state information of the motor, for example, the type of abnormal state, the position where the abnormality occurs, the level of the abnormality, and so on. In some embodiments, the reminder unit 24 may include a display and/or a voice player. In some embodiments, the reminder unit 24 may output information that the state of the motor is normal, to inform the user that the state of the motor is normal and/or the related parameters of the motor operation at this time, etc. It can be understood that the user mentioned above may refer to people, devices, equipment, or systems. For example, in some application scenarios, a distance measuring device (such as a lidar) may include a motor and the motor state monitoring device described above. When the distance measuring device may be disposed on a UAV, a machine, or a vehicle, the user mentioned above may be the control system of a UAV, a robot, or a vehicle.

FIG. 3 is a flowchart of a motor state monitoring method 30 according to an embodiment of the present disclosure. The motor state monitoring method 30 can be used to monitor the state of the motor. The motor state monitoring method 30 will be described in detail below.

31, using a receiver that is not in contact with the motor to receive the measured signal emitted by the motor. The motor may be the motor 100 described above, and the receiver may be the receiver 11 described above.

The measured signal may include one or more of an acoustic signal and an electromagnetic wave signal. In some embodiments, the acoustic signal can be received through an acoustic receiver positioned separately from the motor. The acoustic receiver may include a microphone, an accelerometer, a vibration sensor, a piezoelectric crystal, and/or a barometer. In some embodiments, the electromagnetic wave signal may include one or more of a power frequency electromagnetic wave signal and infrared rays. In some embodiment, the power frequency electromagnetic wave signal can be received through an antenna positioned separately from the motor. In other embodiments, the infrared rays can be received through an infrared receiver tube positioned separately from the motor.

32, determining the state of the motor based on the measured signal and generating a state signal indicating the state of the motor. The signal processing unit 12 and the signal processing unit 22 described above can be used to perform the process at 32.

In some embodiments, the type of the abnormal state and/or the abnormal position of the motor may be determined based on the measured signal.

In some embodiments, the state of the motor may be determined based on the frequency spectrum and/or amplitude of the measured signal. In some embodiments, the state of the motor may be determined based on one or more of the frequency, amplitude, spectrum change, amplitude change, phase size, or phase change of the measured signal. In some embodiments, the state of the motor may be determined to be abnormal when the measured signal includes one or more of the following condition: one or more frequency spectrums in the motor normal state disappear, frequency band outside the frequency spectrum under the motor normal state includes a specific frequency spectrum, the same frequency band repeatedly appears, the time of the frequency spectrum in the motor normal state is abnormal, or the phase of the signal in the frequency spectrum is abnormal. In some embodiments, the frequency band outside the frequency spectrum under the normal state of the motor including a specific frequency spectrum may refer to the appearance of any frequency spectrum in the frequency band outside the frequency spectrum of the motor under the normal state, or it may refer to the appearance of a predetermined spectrum in the frequency band outside the frequency spectrum of the motor under the normal state.

In some embodiments, the state of the motor may be determined by comparing the measured signal with the corresponding signal model. The signal model may include the normal signal model under the normal state of the motor and/or the abnormal signal model under the abnormal state of the motor. In some embodiments, the state of the motor may be determined by comparing the measured signal of the specific frequency band with the signal model of the specified frequency band. In some embodiments, the state of the motor may be determined by comparing the measured signal of the full spectrum with the signal model of the full spectrum.

In some embodiments, when the state of the motor is determined to be normal, the normal state knowledge base can be updated, and the characteristics of the measured signal corresponding to the normal state of the motor may be added into the normal state knowledge base. The normal state knowledge base may include the normal signal models and/or the normal state determination conditions. In some embodiments, when the state of the motor is determined to be abnormal, the abnormal state knowledge base can be updated, and the characteristics of the measured signal corresponding to the abnormal state of the motor may be added into the abnormal state knowledge base. The abnormal state knowledge base may include the abnormal signal models and/or the abnormal state determination conditions.

In some embodiments, the motor state monitoring method may further include detecting an auxiliary measured signal of the motor that is different form the measured signal, and using the auxiliary measured signal to assist in determining the state of the motor. The auxiliary measured signal may be different from the measured signal, and the auxiliary measured signal may include one or more of the current of the motor, the voltage of the motor, the vibration of the motor, or the temperature of the motor.

In some embodiments, the motor state monitoring method may further include converting the measured signal into an electrical signal, processing the electrical signal, and determining the state of the motor based on the processed electrical signal. In some embodiments, the measured signal may be converted into an analog signal, and the analog signal may be converted into a digital signal. The digital signal may be used to process and determine the state of the motor.

In some embodiments, the motor state monitoring method may further include sending out a reminder message when the state of the motor is abnormal. The reminder information may include display information and/or voice information.

In some embodiments, the measured signal may be mixed with nose signals, and the motor state monitoring method may include identifying the measured signal. The measured signal may be identified from the noise signals to avoid the influence of the noise signals on the determination of the state of the motor.

The motor state monitoring device and the motor state monitoring method provided in each embodiment of the present disclosure can be applied to a distance measuring device. The distance measuring device may be an electronic device such as a lidar, a laser distance measuring device, etc. In some embodiments, the distance measuring device may be used to detect external environment information, such as distance information, orientation information, reflection intensity information, speed information, etc. of targets in the environment. In some embodiments, the distance measuring device may detect the distance between an object to be detected and the distance measuring device by measuring the time of light propagation between the distance measuring device and the object to be detected, that is, the time-of-flight (TOF). Alternatively, the distance measuring device may also detect the distance between the object to be detected and the distance measuring device through other technologies, such as a distance measuring method based on phase shift measurement or a distance measuring method based on frequency shift measurement, which is not limited in the embodiments of the present disclosure.

For ease of understanding, the working process of distance measurement will be described by an example in conjunction with a distance measuring device 100 shown in FIG. 4.

As shown in FIG. 4, the distance measuring device 100 includes a transmitting circuit 110, a receiving circuit 120, a sampling circuit 130, and an arithmetic circuit 140.

The transmitting circuit 110 may emit a light pulse sequence (e.g., a laser pulse sequence). The receiving circuit 120 may receive the light pulse sequence reflected by the object to be detected, and perform photoelectric conversion on the light pulse sequence to obtain an electrical signal. After the electrical signal is processed, it may be output to the sampling circuit 130. The sampling circuit 130 may sample the electrical signal to obtain a sampling result. The arithmetic circuit 140 may determine the distance between the distance measuring device 100 and the object to be detected based on the sampling result of the sampling circuit 130.

In some embodiments, the distance measuring device 100 may also include a control circuit 150, the control circuit 150 may be used to control other circuits. For example, the control circuit 150 may control the working time of each circuit and/or set the parameters of each circuit.

It can be understood that although the distance measuring device shown in FIG. 4 includes a transmitting circuit, a receiving circuit, a sampling circuit, and an arithmetic circuit, the embodiments of the present disclosure are not limited thereto. The number of any one of the transmitting circuit, the receiving circuit, the sampling circuit, and the arithmetic circuit may also be two or more.

In some embodiments, in addition to the circuits shown in FIG. 4, the distance measuring device 100 may further include a scanning module 160. The scanning module 160 may be used to change the propagation direction of the laser pulse sequence emitted by the transmitting circuit and emit it.

In some embodiments, a module including the transmitting circuit 110, the receiving circuit 120, the sampling circuit 130, and the arithmetic circuit 140 or a module including the transmitting circuit 110, the receiving circuit 120, the sampling circuit 130, the arithmetic circuit 140, and the control circuit 150 can be referred to as a distance measurement module. The distance measurement module may be independent of other modules, such as the scanning module.

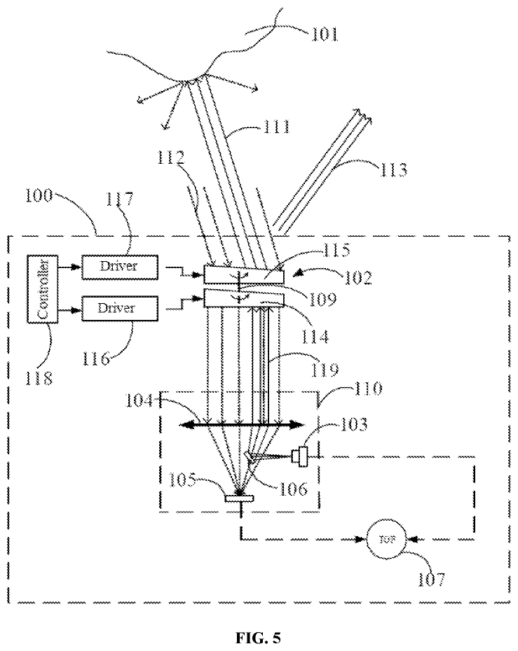

A coaxial optical path can be used in the distance measuring device. That is, the light beam emitted by the distance measuring device and the reflected light beam can share at least part of the optical path in the distance measuring device. Alternatively, the distance measuring device may also use an off-axis optical path. That is, the light beam emitted by the distance measuring device and the reflected light beam can be transmitted along different optical paths in the distance measuring device. FIG. 5 is a block diagram of the distance measuring device using a coaxial optical path according to an embodiment of the present disclosure.

The distance measuring device 100 includes an optical transceiver 110. The optical transceiver 110 includes a light source 103 (including the transmitting circuit described above), a collimating element 104, and a detector 105 (which may include the receiving circuit, the sampling circuit, and the arithmetic circuit described above), and an optical path changing element 106. The optical transceiver 110 may be used to emit light beams, receive returned light, and convert the returned light into electrical signals. The light source 103 may be used to emit a light beam. In some embodiments, the light source 103 may emit a laser beam. In some embodiments, the laser beam emitted by the light source 103 may be a narrow-bandwidth beam with a wavelength outside the visible light range. The collimating element 104 may be disposed on the exit light path of the light source, and configured to collimate the light beam emitted from the light source 103 and collimate the light beam emitted from the light source 103 into parallel light. The collimating element 104 may also be configured to condense at least a part of the returned light reflected by the object to be detected. The collimating element 104 may be a collimating lens or other elements capable of collimating light beams.

In the embodiment shown in FIG. 5, the optical path changing element 106 may combine the transmitting light path and the receiving light path in the distance measuring device before the collimating element 104, such that the transmitting light path and the receiving light path can share the same collimating element, making the light path more compact. In other embodiments, the light source 103 and the detector 105 may use respective collimating elements, and the optical path changing element 106 may be disposed behind the collimating elements.

In the embodiment shown in FIG. 5, since the beam divergence angle of the light beam emitted by the light source 103 is relatively small, and the beam divergence angle of the returned light received by the distance measuring device is relatively large, the optical path changing element 106 may use a small reflector to combine the transmitting light path and the receiving light path. In other embodiments, the optical path changing element 106 may also be a reflector with a through hole, where the through hole can be used to transmit the emitted light of the light source 103, and the reflector may be used to reflect the returned light to the detector 105. In this way, the chances of the support of the small reflector blocking the returned light can be reduced.

In the embodiment shown in FIG. 5, the optical path changing element 106 deviates from the optical axis of the collimating element 104. In other embodiments, the optical path changing element 106 may also be positioned on the optical axis of the collimating element 104.

The distance measuring device 100 further includes a scanning module 102. The scanning module 102 may be positioned on the exit light path of the optical receiver 100. The scanning module 102 may be used to change the transmission direction of a collimated light beam 119 emitted by the collimating element 104, project the collimated light beam 119 to the external environment, and project the returned light to the collimating element 104. The returned light can be collected on the detector 105 via the collimating element 104.

In some embodiments, the scanning module 102 may include one or more optical elements, such as lens, mirrors, prisms, optical phased array, or any combination of the above optical elements. In some embodiments, the plurality of optical elements of the scanning module 102 may rotate around a common axis 109, an each rotating optical element may be used to continuously change the propagation direction of the incident light beam. In some embodiments, the plurality of optical elements of the scanning module 102 may rotate at different speeds. In other embodiments, the plurality of optical elements of the scanning module 102 may rotate at substantially the same speed.

In some embodiments, the plurality of optical elements of the scanning module 102 may also rotate around different axes. In some embodiments, the plurality of optical elements of the scanning module 102 may also rotate in the same direction or in different directions, or vibrate in the same direction or different directions, which is not limited in the embodiments of the present disclosure.

In some embodiments, the scanning module 102 may include a first optical element 114 and a driver 116 connected to the first optical element 114. The driver 116 can be used to drive the first optical element 114 to rotate around the rotation axis 109 such that the first optical element 114 can change the direction of the collimated light beam 119. The first optical element 114 can project the collimated light beam 119 to different directions. In some embodiments, the angle between the direction of the collimated light beam 119 changed by the first optical element 114 and the rotation axis 109 may change as the first optical element 114 rotates. In some embodiments, the first optical element 114 may include a pair of opposite non-parallel surface through which the collimated light beam 119 can pass. In some embodiments, the first optical element 114 may include a prism whose thickness may vary along one or more radial directions. In some embodiments, the first optical element 114 may include a wedge-angle prism to refract the collimated light beam 119. In some embodiments, the first optical element 114 may be coated with an anti-reflection coating, and the thickness of the anti-reflection coating may be equal to the wavelength of the light beam emitted by the light source 103, which can increase the intensity of the transmitted light beam.

In some embodiments, the scanning module 102 may further include a second optical element 115. The second optical element 115 may rotate around the rotation axis 109, and the rotation speed of the second optical element 115 may be different from the rotation speed of the first optical element 114. The second optical element 115 may be used to change the direction of the light beam projected by the first optical element 114. In some embodiments, the second optical element 115 may be connected to a driver 117, and the driver 117 can drive the second optical element 115 to rotate. The first optical element 114 and the second optical element 115 can be driven by different drivers, such that the rotation speed of the first optical element 114 and the second optical element 115 can be different, such that the collimated light beam 119 can be projected to different directions in the external space, and a larger spatial range can be scanned. In some embodiments, a controller 118 may be used to control the driver 116 and the driver 117 to drive the first optical element 114 and the second optical element 115, respectively. The rotation speeds of the first optical element 114 and the second optical element 115 may be determined based on the area and pattern expected to be scanned in actual applications. The driver 116 and the driver 117 may include motors or other driving devices.

In some embodiments, the second optical element 115 may include a pair of opposite non-parallel surfaces through which the light beam can pass. In some embodiments, the second optical element 115 may include a prism whose thickness may vary in one or more radial directions. In some embodiments, the second optical element 115 may include a wedge prism. In some embodiments, the second optical element 115 may be coated with an anti-reflection coating to increase the intensity of the transmitted light beam.

The rotation of the scanning module 102 may project light in different directions, such as directions 111 and 113. In this way, the space around the distance measuring device 100 can be scanned. When the light projected by the scanning module 102 hits an object to be detected 101, a part of the light may be reflected by the object to be detected 101 to the distance measuring device 100 in a direction opposite to direction 111. The scanning module 102 can may receive a returned light 112 reflected by the object to be detected 101 and project the returned light 112 to the collimating element 104.

The collimating element 104 may converge at least a part of the returned light 112 reflected by the object to be detected 101. In some embodiments, an anti-reflection coating may be coated on the collimating element 104 to increase the intensity of the transmitted light beam. The detector 105 and the light source 103 may be disposed on the same side of the collimating element 104, and the detector 105 may be used to convert at least part of the returned light passing through the collimating element 104 into an electrical signal.

In some embodiments, the light source 103 may include a laser diode through which nanosecond laser light can be emitted. For example, the laser pulse emitted by the light source 103 may last for 10 ns. Further the laser pulse receiving time may be determined, for example, by detecting the rising edge time and/or falling edge time of the electrical signal pulse to determine the laser pulse receiving time. In this way, the distance measuring device 100 may calculate the TOF using the pulse receiving time information and the pulse sending time information, thereby determining the distance between the object to be detected 101 and the distance measuring device 100.

In some embodiments, the motor may include a rotor assembly, a stator assembly, and a positioning assembly around a rotating shaft. In some embodiments, the rotor assembly may include an inner wall surrounding the rotating shaft, and the inner wall may be formed with a receiving cavity capable of accommodating a prism. The stator assembly may be used to drive the rotor assembly to rotate around the rotating shaft. The positioning assembly may be positioned outside the receiving cavity and configured to limit the rotation of the rotor assembly centered on a fixed rotating shaft. In some embodiments, the rotor assembly, the stator assembly, and the positioning assembly may respectively have an overall ring structure. The stator assembly and the positioning assembly may surround the rotor assembly in a side by side manner. In some embodiments, the positioning assembly may include an annular bearing. The annular bearing may surround the outside of the inner wall. In some embodiments, the motor may be fixed in a housing. In addition, the bearing may include an inner ring structure, an outer ring structure, and rolling elements. The inner ring structure and the outer side of the inner wall may be fixed to each other, the outer ring structure and the housing may be fixed to each other, the rolling elements may be positioned between the inner ring structure and the outer ring structure. The rolling elements may be used for the rolling connection with the outer ring structure and the inner ring structure, respectively.

In some embodiments, the distance and orientation detected by the distance measuring device 100 can be used for remote sensing, obstacle avoidance, surveying and mapping, modeling, navigation, and the like.

In some embodiments, the distance measuring device of the embodiments of the present disclosure may be applied to a movable platform. For example, the distance measuring device may be mounted to a main body of the movable platform. The movable platform can perform a measurement of an external environment through the distance measuring device. For example, the distance measuring device may be configured to measure a distance between the movable platform and an obstacle, which may be used for obstacle avoidance. As another example, the distance measuring device may be configured to perform a two-dimensional or three-dimensional survey of the external environment.

In some embodiments, the movable platform may include at least one of an unmanned aircraft, a vehicle, a remote control vehicle, a robot, or a camera. When the distance measuring device is implemented in an unmanned aircraft, the main body of the movable platform may be the aircraft body of the unmanned aircraft. When the distance measuring device is implemented in a vehicle, the main body of the movable platform may be the body of the vehicle. The vehicle can be a self-driving vehicle or a semi-self-driving vehicle, which is not limited in the embodiments of the present disclosure. When the distance measuring device is implemented in a remote control vehicle, the main body of the movable platform may be the body of the remote control vehicle. When the distance measuring device is implemented in a robot, the main body of the movable platform may be the body of the robot. When the distance measuring device is implemented in a camera, the main body of the movable platform may be the body of the camera.

Since the method embodiments correspond to device embodiments, related parts may be made referred to the description of the device embodiments. The method embodiments and the device embodiments complement each other.

It should be noted that in the present disclosure, relational terms such as first and second, etc., are only used to distinguish an entity or operation from another entity or operation, and do not necessarily imply that there is an actual relationship or order between the entities or operations. The terms “comprising,” “including,” or any other variations are intended to encompass non-exclusive inclusion, such that a process, a method, an apparatus, or a device having a plurality of listed items not only includes these items, but also includes other items that are not listed, or includes items inherent in the process, method, apparatus, or device. Without further limitations, an item modified by a term “comprising a . . . ” does not exclude inclusion of another same item in the process, method, apparatus, or device that includes the item.

The method and device provided in embodiments of the present disclosure have been described in detail above. In the present disclosure, particular examples are used to explain the principle and embodiments of the present disclosure, and the above description of embodiments is merely intended to facilitate understanding the methods in the embodiments of the disclosure and concept thereof; meanwhile, it is apparent to persons skilled in the art that changes can be made to the particular implementation and application scope of the present disclosure based on the concept of the embodiments of the disclosure, in view of the above, the contents of the specification shall not be considered as a limitation to the present disclosure.

What is claimed is:

1. A motor state monitoring device, comprising:
a receiver disposed separately from a motor and configured to receive a measured signal emitted by the motor without contact; and
a signal processing unit connected to the receiver and configured to determine a state of the motor based on the measured signal, and generate a state signal indicating the state of the motor.

2. The motor state monitoring device of claim 1, wherein:
the receiver includes an acoustic receiver configured to receive an acoustic signal, the acoustic receiver including a microphone, an accelerometer, a vibration sensor, a piezoelectric crystal, and a barometer.

3. The motor state monitoring device of claim 1, wherein:
the signal processing unit is configured to determine a type of an abnormal state of the motor and an abnormal position of the motor based on the measured signal.

4. The motor state monitoring device of claim 1, wherein:
the signal processing unit is configured to determine the state of the motor based on one or more of a frequency spectrum, an amplitude, or a phase of the measured signal.

5. The motor state monitoring device of claim 4, wherein:
the signal processing unit is configured to determine the state of the motor based on one or more of a bandwidth, the frequency, the amplitude, a spectrum change, an amplitude change, a phase size, or a phase change of the measured signal.

6. The motor state monitoring device of claim 4, wherein:
the signal processing unit is configured to determine the state of the motor is abnormal when the one or more conditions of one or more frequency spectrums in a normal state of the motor disappears, a frequency band outside a frequency spectrum under the normal state of the motor includes a specific frequency spectrum, a same frequency band repeatedly appears, a time of the frequency spectrum in the normal state of the motor is abnormal, or a phase of the signal in the frequency spectrum is abnormal occur in the measured signal.

7. The motor state monitoring device of claim 1, wherein:
the signal processing unit is configured to compare the measured signal with a corresponding signal model to determine the state of the motor, the signal model including a normal signal model in a normal state of the motor and an abnormal signal model in an abnormal state of the motor.

8. The motor state monitoring device of claim 7, wherein:
the signal processing unit is configured to compare the measured signal of a designated frequency band with a signal model of the designated frequency band to determine the state of the motor.

9. The motor state monitoring device of claim 7, wherein:
the signal processing unit is configured to compare the measured signal of a full spectrum with a signal model of the full spectrum to determine the state of the motor.

10. The motor state monitoring device of claim 7, wherein:
the signal processing unit is configured to update a normal state knowledge base when the state of the motor is determined to be normal, and add characteristics of the measured signal corresponding to the normal state of the motor into the normal state knowledge base, the normal state knowledge base including normal signal models and normal state determination conditions.

11. The motor state monitoring device of claim 7, wherein:
the signal processing unit is configured to update an abnormal state knowledge base when the state of the motor is determined to be abnormal, and add characteristics of the measured signal corresponding to the abnormal state of the motor into the abnormal state knowledge base, the abnormal state knowledge base including abnormal signal models and abnormal state determination conditions.

12. A motor state monitoring method, comprising:
using a receiver to receive a measured signal emitted by a motor without contact; and
determining a state of the motor based on the measured signal, and generating a state signal indicating the state of the motor.

13. The motor state monitoring method of claim 12, wherein receiving the measured signal emitted by the motor without contact includes:
receiving an acoustic signal by using an acoustic receiver positioned separately from the motor, the acoustic receiver including a microphone, an accelerometer, a vibration sensor, a piezoelectric crystal, and a barometer.

14. The motor state monitoring method of claim 12, wherein determining the state of the motor based on the measured signal includes:
determining a type of an abnormal state of the motor and an abnormal position of the motor based on the measured signal.

15. The motor state monitoring method of claim 12, wherein determining the state of the motor based on the measured signal includes:
determining the state of the motor based on one or more of a frequency spectrum, an amplitude, or a phase of the measured signal.

16. The motor state monitoring method of claim 15, wherein determining the state of the motor based on one or more of the frequency spectrum, the amplitude, or the phase of the measured signal includes:
determining the state of the motor based on one or more of the frequency, the amplitude, a spectrum change, an amplitude change, a phase size, or a phase change of the measured signal.

17. The motor state monitoring method of claim 15, wherein determining the state of the motor based on the frequency spectrum and the amplitude of the measured signal includes:
determining the state of the motor is abnormal when the one or more conditions of one or more frequency spectrums in a normal state of the motor disappears, a frequency band outside a frequency spectrum under the normal state of the motor includes a specific frequency spectrum, a same frequency band repeatedly appears, a time of the frequency spectrum in the normal state of the motor is abnormal, or a phase of the signal in the frequency spectrum is abnormal occur in the measured signal.

18. The motor state monitoring method of claim 12, wherein determining the state of the motor based on the measured signal includes:
comparing the measured signal with a corresponding signal model to determine the state of the motor, the signal model including a normal signal model in a normal state of the motor and an abnormal signal model in an abnormal state of the motor.

19. The motor state monitoring method of claim 18, wherein comparing the measured signal and the corresponding signal model to determine the state of the motor includes:
comparing the measured signal of a designated frequency band with a signal model of the designated frequency band to determine the state of the motor.

20. The motor state monitoring method of claim 18, wherein comparing the measured signal and the corresponding signal model to determine the state of the motor includes:
comparing the measured signal of a full spectrum with a signal model of the full spectrum to determine the state of the motor.

21. The motor state monitoring method of claim 18, further comprising:
updating a normal state knowledge base when the state of the motor is determined to be normal; and
adding characteristics of the measured signal corresponding to the normal state of the motor into the normal state knowledge base, the normal state knowledge base including normal signal models and normal state determination conditions.

22. The motor state monitoring method of claim 18, further comprising:
updating an abnormal state knowledge base when the state of the motor is determined to be abnormal; and
adding characteristics of the measured signal corresponding to the abnormal state of the motor into the abnormal state knowledge base, the abnormal state knowledge base including abnormal signal models and abnormal state determination conditions.

23. A distance measuring device, comprising:
a scanning module including a motor and a prism with uneven thickness, the motor being configured to drive the prism to rotate; and
a motor state monitoring device configured to monitor a state of the motor, the motor state monitoring device including:
a receiver disposed separately from the motor and configured to receive a measured signal emitted by the motor without contact; and
a signal processing unit connected to the receiver and configured to determine the state of the motor based on the measured signal, and generate a state signal indicating the state of the motor.
